(19) United States
(12) Patent Application Publication
(10) Pub. No.: US 2024/0395596 A1
(43) Pub. Date: Nov. 28, 2024

(54) PASSIVE GRAVITY COMPENSATOR FOR SEMICONDUCTOR EQUIPMENT

(71) Applicant: ETEL S.A., Môtiers (CH)

(72) Inventors: Manish MITTAL, Neuchâtel (CH); Jean-Pierre MOREL, Les Fourgs (FR)

(21) Appl. No.: 18/666,199

(22) Filed: May 16, 2024

(30) Foreign Application Priority Data
May 24, 2023 (EP) 23175027.4

(51) Int. Cl. H01L 21/687; H01F 7/02

(52) U.S. Cl. CPC H01L 21/68785; H01F 7/02

(57) ABSTRACT

A passive gravity compensator for a semiconductor equipment, which includes a stationary unit and a movable unit adapted to move relative the stationary unit in a Z-direction, includes a first assembly and a second assembly. The first assembly includes a magnet holder and a permanent magnet fixed to the magnet holder. The second assembly includes a magnetic yoke having first and second opposite parts and first and second permanent magnets mounted against the first and second opposite parts of the magnetic yoke to face each other and to form a gap therebetween. One of the first and second assemblies of the gravity compensator is adapted to be mounted on the stationary unit of the semiconductor equipment, and the other of the first and second assemblies of the gravity compensator is adapted to be mounted to the movable unit of the semiconductor equipment, such that the permanent magnet of the first assembly is movable inside the gap located between the first and second permanent magnets of the second assembly. The gravity compensator further includes a force adjustment device adapted to be mounted on the stationary unit of the semiconductor equipment. The force adjustment device is adapted to adjust the relative position between the permanent magnet of the first assembly and the first and second permanent magnets of the second assembly along an X or Y direction to adjust the gravity compensation force.

### CROSS-REFERENCE TO RELATED APPLICATIONS

The present application claims priority to Application No. 23175027.4, filed in the European Patent Office on May 24, 2023, which is expressly incorporated herein in its entirety by reference thereto.

### FIELD OF THE INVENTION

The present invention relates to a passive gravity compensator for semiconductor processing equipment, e.g., a wafer holder, including, for example, a stationary unit and a moveable unit adapted to move in a Z-direction relative to the stationary unit. The present invention also relates to semiconductor equipment including such a passive gravity compensator.

### BACKGROUND INFORMATION

In certain applications, such as in the production of semiconductors, wafer tables that are used to support and to process wafers are typically able to move in the vertical Z-direction. The weight of such wafer tables needs to be supported against the force of gravity by either an active or a passive gravity-compensation device to reduce or eliminate the effect of the gravity force. Active gravity-compensation devices use actuators to generate the required forces to cancel the gravity forces acting on the semiconductor process equipment. The active gravity-compensation devices provide compensation capability in a more controllable fashion but are more complicated than passive gravity-compensation devices.

Passive gravity-compensation devices are thus less expensive, more reliable, and more durable. Therefore, these passive devices are usually preferred over active devices when they can meet the requirements of a specific application.

Chinese Patent Document No. 107885039 describes an adjustable passive gravity compensator for semiconductor processing equipment, which includes a fixed assembly and a movable assembly. The movable assembly includes an inner ring magnet and an outer ring magnet mounted in a magnet housing and arranged concentrically relative to the inner ring magnet.

The fixed assembly includes a cylindrical magnet around which the inner ring magnet of the moveable assembly is mounted. The position of the cylindrical magnet can be adjusted in the Z direction to adjust to the compensating force of the gravity compensator.

### SUMMARY

Example embodiments of the present invention provide a passive gravity compensator with a force adjustment device.

According to example embodiments, a passive gravity compensator for a semiconductor equipment including a stationary unit and a movable unit adapted to move relative the stationary unit in a Z-direction, includes a first assembly having a magnet holder and a permanent magnet fixed to the magnet holder. The gravity compensator further includes a second assembly, including a magnetic yoke having first and second opposite parts and first and second permanent magnets mounted against the first and second opposite parts of the magnetic yoke to face each other and to form a gap therebetween. One and the other of first and second assemblies of the gravity compensator are adapted to be mounted on respectively the stationary unit and movable unit of the semiconductor equipment such that the permanent magnet of the first assembly is movable inside the gap between the first and second permanent magnets of the second assembly. The gravity compensator further includes a force adjustment device adapted to be mounted on the stationary unit of the semiconductor equipment and adapted to adjust the relative position between the permanent magnet of the first assembly and the first and second permanent magnets of the second assembly along a direction perpendicular to the Z-direction, e.g., along an X- or Y-direction, to adjust the gravity compensation force.

According to example embodiments, the force adjustment device includes a guiding system connected to one of the first and second assemblies and an adjustment device adapted to move the first assembly toward to or away from the second assembly along the X- or Y-direction.

According to example embodiments, the guiding system includes a rail, a slider slidably mounted on the rail, and a bracket fixed to the slider. The bracket includes a base supporting the one of the first and second assemblies and two lateral sides facing two opposite sides of the slider. The adjustment device includes a screw mounted on a through-hole on each lateral side of the bracket to move the bracket in either of two opposite directions by screwing and unscrewing the screws.

According to example embodiments, the screws are arranged to abut against to opposite sides of the rail and are arranged to work in opposition to create a pre-constraint on the guiding system in order to prevent the screws from loosening up over time.

According to example embodiments, the magnetic yoke includes a rectangular parallelepiped shaped rear part and two opposite rectangular parallelepiped shaped parts extending perpendicularly from the rear part. The first and second permanent magnets are mounted on two opposite inner sides of the two opposite rectangular parallelepiped shaped parts.

According to example embodiments, the magnetic yoke has an external envelope of rectangular parallelepiped shape. The magnetic yoke has a U-shaped transverse cross-section which is constant along the displacement direction of the first assembly relative to the second assembly of the gravity compensator.

According to example embodiments, the magnet holder of the first assembly includes a frame having an opening inside of which is mounted the permanent magnet with two opposite sides facing the first and second permanent magnets of the second assembly.

According to example embodiments, the first assembly further includes two L-shaped lateral parts mounted on both sides of the frame and within the same plane of respective opposite parts of the magnetic yoke.

According to example embodiments, the polarity of the permanent magnet of the first assembly and the polarity of the first and second permanent magnets of the second assembly are oriented in the same direction.

According to example embodiments, semiconductor equipment, e.g., a wafer holder, includes a stationary unit, a movable unit arranged to move relative the stationary unit in a Z-direction, and gravity compensator, as described herein.

The force adjustment device is part of the first assembly of the gravity compensator. The first assembly is mounted on the stationary unit, whereas the second assembly is mounted in the movable unit of the semiconductor equipment such that the permanent magnet of the first assembly is movable, at least partly, inside the gap between the first and second permanent magnets of the second assembly.

According to example embodiments, the magnetic yoke includes through-holes and screws arranged in the through-holes and screwed into the movable unit.

Further features and aspects of example embodiments of the present invention are described in more detail below with reference to the appended schematic Figures.

### BRIEF DESCRIPTION OF THE DRAWINGS

FIG. 1 is a perspective view of a wafer holder, which includes a stationary unit, a movable unit adapted to move relative the stationary unit in a Z-direction, and a gravity compensator, in which the force adjustment device of the gravity compensator is set in a first position to provide the maximum gravity compensation force.

FIG. 2a is a perspective view of the gravity compensator.

FIG. 2b is a side view of the gravity compensator.

FIG. 2c is a top view of the gravity compensator.

FIG. 3 is a perspective view of the wafer holder illustrated in FIG. 1, with the force adjustment device of the gravity compensator set in a second position to provide an intermediate gravity compensation force.

FIG. 4a is a perspective view of the gravity compensator.

FIG. 4b is a side view of the gravity compensator.

FIG. 4c is a top view of the gravity compensator.

FIGS. 5a to Sc are side views of the gravity compensator, with three different Z positions of the first assembly with respect to the second assembly.

FIG. 6 is a graph illustrates the gravity compensation force as a function of the position of the first assembly with respect to the second assembly in the Z-direction.

FIGS. 7a to 7c are top views of the gravity compensator with three different X positions of the first assembly with respect to the second assembly.

FIG. 8 is a graph illustrating the gravity compensation force as a function of the position of the first assembly with respect to the second assembly in the X-direction.

### DETAILED DESCRIPTION

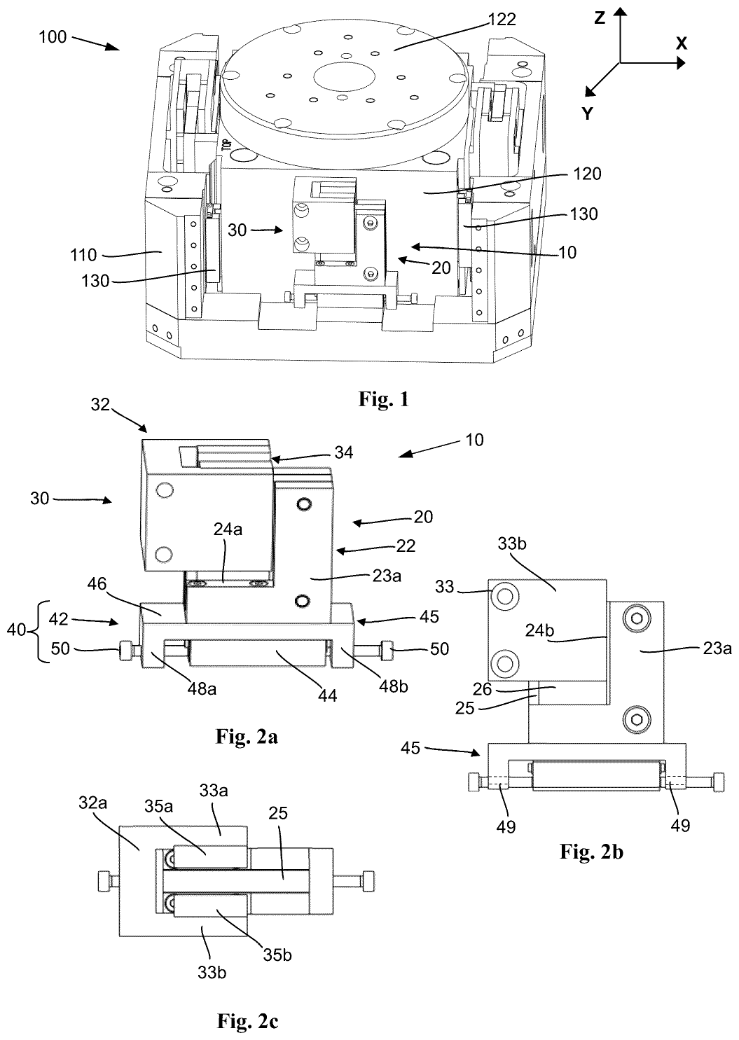

FIG. 1 illustrates a wafer holder 100 that includes a stationary unit 110, a movable unit 120 including a wafer chuck 122, and linear bearings 130 mounted between the stationary and movable units 110, 120 to guide the movable unit 120 relative to the stationary unit 110 along a Z-direction. The wafer holder 100 further includes a gravity compensator 10. The gravity compensator 10 includes a first assembly 20 fixed to the stationary unit 110 and a second assembly 30 fixed to the movable unit 120 of the wafer holder 100.

Referring to FIGS. 2a to 2c, the first assembly 20, also referred to as the fixed assembly, includes a magnet holder 22 and a permanent magnet 26 fixed to the magnet holder 22. More particularly, the magnet holder 22 includes a non-magnetic frame 25 having an opening inside of which is mounted the permanent magnet 26. Two opposite sides of the magnet 26 extend in the plane of respective opposite sides of the frame 25. The magnet holder 22 further includes two L-shaped lateral parts 23a, 23b mounted on both sides of the frame 25, and including a first linear edge 24a and a second linear edge 24b extending orthogonally from an end of the first linear edge 24a.

The second assembly 30, also referred to as the mobile assembly, includes a magnetic yoke 32 having a rectangular parallelepiped shaped rear part 32a and two opposite rectangular parallelepiped shaped parts 33a, 33b extending perpendicularly from the rear part 32a toward the second linear edge 24b of respective lateral parts 23a, 23b of the magnet holder 22. The magnetic yoke 32 has an external envelope of rectangular parallelepiped shape with a U-shaped transverse cross-section that is constant along the displacement direction of the mobile assembly 30 relative to the fixed assembly 20 of the gravity compensator 10.

The mobile assembly 30 further includes first and second permanent magnets 35a, 35b mounted on two opposite inner sides of respective opposite rectangular parallelepiped shaped parts 33a, 33b to face each other and to form a gap 34 therebetween.

The frame 25 of the magnet holder 22 of the fixed assembly 20 is mounted inside the gap 34 of the mobile assembly 30 such that the permanent magnet 26 is movable relative to the two opposite permanent magnet 35a, 35b along the Z-direction.

The rear part 32a of magnetic yoke 32 includes through-holes 33 extending between two opposite sides. These through-holes 33 are adapted to receive screws for fixing the mobile assembly 30 to the movable unit 120 of the wafer holder 100.

The gravity compensator 10 further includes a force adjustment device 40 adapted to adjust the relative position between the permanent magnet 26 of the fixed assembly 20 and the first and second permanent magnets 35a, 35b of the mobile assembly 30 along a X or Y direction to adjust the gravity compensation force.

More particularly, the force adjustment device 40 includes a guiding system 42, which is part of the fixed assembly 20, and which is fixed to the stationary unit 110 of the wafer holder 100. More particularly, the guiding system 42 includes a rail 43, screwed onto to the stationary unit 110, a slider 44 slidably mounted on the rail 43, and a bracket 45 fixed to the slider 44. The bracket 45 includes a base 46 onto which is mounted the magnet holder 22 and two lateral sides 48a, 48b facing two opposite sides of the slider 44.

The adjustment device includes a screw 50 mounted on a through-hole 49 on each lateral side 48a, 48b of the bracket 45 to abut with respective opposite sides of the rail 43. The bracket 45 can thus be moved in either of two opposite directions by screwing and unscrewing the respective screw 50 to move the fixed assembly 20 toward to or away from the mobile assembly 30. The screws 50 work in opposition to be able to create a pre-constraint on the rail 43, thereby preventing the screws loosening up with time.

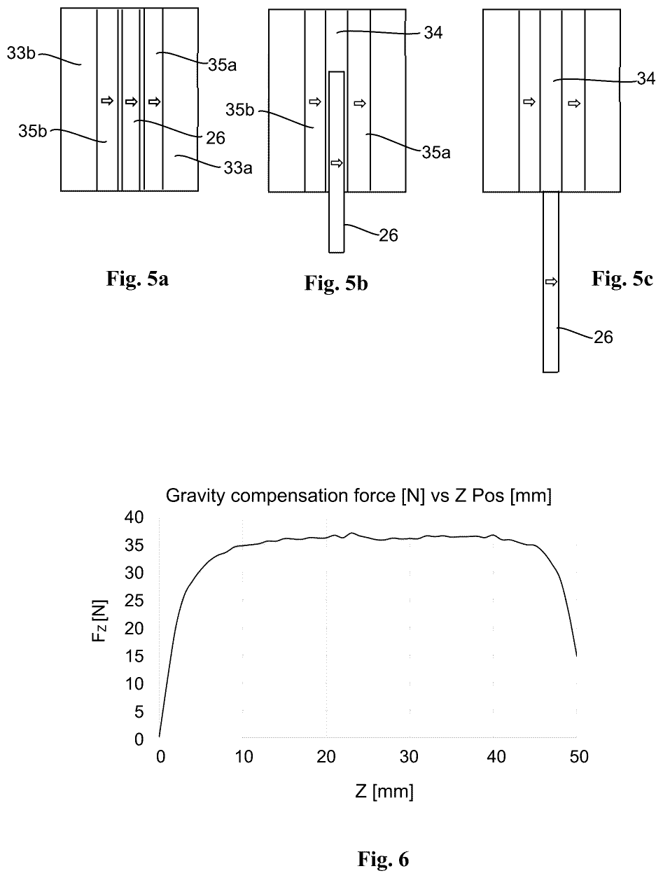

FIGS. 5a to 5c illustrate three different Z positions of the mobile assembly with respect to the fixed assembly. The polarity of the permanent magnet 26 of the first assembly and the polarity of the first and second permanent magnets 35a, 35b of the second assembly are oriented in the same direction.

Due to magnetic interaction between the two assemblies, a force is generated in the Z direction. This Z force is constant over a stroke length. For example, the relative position between the mobile and fixed assemblies provides 35 N of gravity compensation force constant over a stroke of 30 mm, as illustrated in FIG. 6.

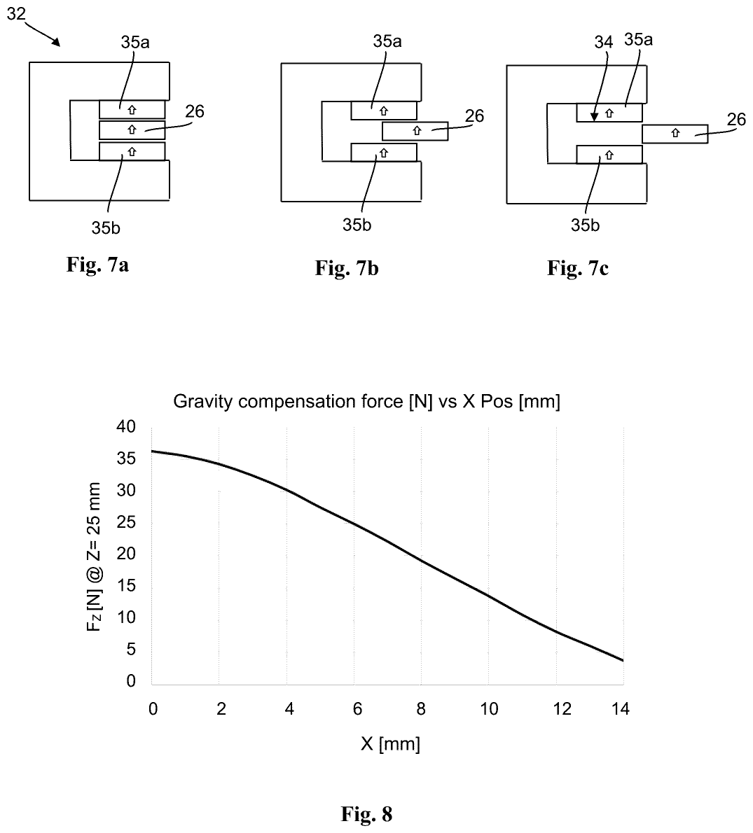

FIGS. 7a to 7c illustrate three different X positions of the mobile assembly with respect to the fixed assembly. The gravity compensation force can be controlled by varying the X position of the static assembly by the adjustment device 50 of the force adjustment device 40, as described above. The force adjustment device 40 may therefore provide a gravity compensation force that is adjustable in the range of, e.g., 5 to 35 N, as illustrated in FIG. 8.

Referring to FIG. 8, there is ±10% variation in force with ±1 mm of X-variation. Precision in forces required can be controlled by choosing the correct precision of the screws.

Generally, ±10% variation in force is considered acceptable, therefore a standard screw with a precision of ±1 mm can be used.

Referring again to FIGS. 1 and FIGS. 2a to 2c, the force adjustment device 40 of the gravity compensator 10 is set in a first position to provide the maximum gravity compensation force on the order of 35 N. In this position, the two opposite parts 33a, 33b of the magnetic yoke 32 are nearly in contact with the second linear edge 24b of respective lateral parts 23a, 23b of the magnet holder 22 of the first assembly, leaving a small gap in the range of 0.1 mm to allow a contactless movement in the Z direction of the movable unit 120.

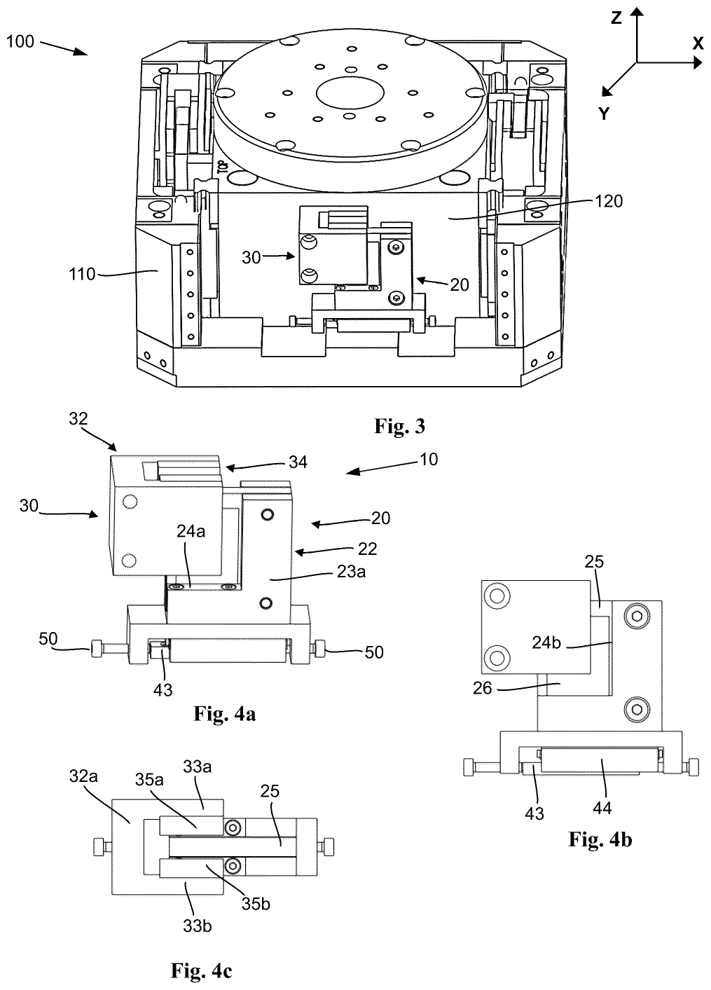

Referring to FIGS. 3 and FIGS. 4a to 4c, the force adjustment device 40 of the gravity compensator 10 is set in a second position to provide an intermediate gravity compensation force on the order of 20 to 25 N, as illustrated in FIG. 8.

In addition to the foregoing, for example, the first assembly 20 may be adapted to be fixed to the movable unit 120 of the semiconductor equipment 100, whereas the second assembly 30 may be adapted to be fixed to the stationary unit 110 of the semiconductor equipment.

### LIST OF REFERENCE NUMERALS

10 Passive gravity compensator
20 First assembly
22 Magnet holder
23a, 23b Lateral parts
24a, 24b First and second linear edges
25 Frame
26 Permanent magnet
30 Second assembly
32 Magnetic yoke
32a Rear side
33 Through-holes
33a, 33b Opposite sides
34 Gap
35a, 35b Permanent magnets
40 Force adjustment device
42 Guiding system
43 Rail
44 Slider
45 Bracket
46 Base
48a, 48b Lateral sides
49 Threaded through-hole
50 Adjustment device, e.g. screws
100 Wafer holder
110 Stationary unit
120 Movable unit
122 Wafer chuck
130 Linear bearing

What is claimed is:

1. A passive gravity compensator for semiconductor equipment that includes a stationary unit and a movable unit adapted to move relative the stationary unit in a Z-direction, the gravity compensator comprising:
a first assembly including a magnet holder and a permanent magnet fixed to the magnet holder;
a second assembly including a magnetic yoke having first and second opposite parts, a first permanent magnet mounted against the first opposite part of the magnetic yoke, and a second permanent magnet mounted against the second opposite part of the magnetic yoke, the first and second permanent magnets facing each other, a gap being located between the first and second permanent magnets; and
a force adjustment device adapted to be mounted on the stationary unit;
wherein a first one of the first and second assemblies is adapted to be mounted on the stationary unit and a second one of the first and second assemblies is adapted to be mounted on the movable unit such that the permanent magnet of the first assembly is movable inside the gap between the first and second permanent magnets of the second assembly; and
wherein the force adjustment device is adapted to adjust a relative position between the permanent magnet of the first assembly and the first and second permanent magnets of the second assembly along a direction orthogonal to the Z-direction to adjust a gravity compensation force.

2. The passive gravity compensator according to claim 1, wherein the force adjustment device is adapted to adjust the relative position between the permanent magnet of the first assembly and the first and second permanent magnets of the second assembly along an X- or Y-direction orthogonal to the Z-direction to adjust the gravity compensation force.

3. The passive gravity compensator according to claim 1, wherein the force adjustment device includes a guide system connected to one of the first and second assemblies and an adjustment device adapted to move the first assembly toward or away from the second assembly along the direction orthogonal to the Z-direction.

4. The passive gravity compensator according to claim 3, wherein the guide system includes a rail, a slider slidably mounted on the rail, and a bracket fixed to the slider and including a base supporting one of the first and second assemblies and two lateral sides facing two opposite sides of the slider, the adjustment device including a screw mounted in a through-hole on each lateral side of the bracket and adapted to move the bracket in either of two opposite directions by screwing and unscrewing each screw.

5. The passive gravity compensator according to claim 4, wherein each screw is adapted to abut against a respective one of two opposite sides of the rail and are adapted to cooperate in opposition each other to create a pre-constraint on the guiding system to prevent the screws from loosening up over time.

6. The passive gravity compensator according to claim 1, wherein the magnetic yoke includes a rectangular parallelepiped shaped rear part and two opposite rectangular parallelepiped shaped parts extending perpendicularly from the rear part, each of the first and second permanent magnets of the second assembly being mounted on a respective one of two opposite inner sides of the two opposite rectangular parallelepiped shaped parts.

7. The passive gravity compensator according to claim 1, wherein the magnetic yoke has an external envelope of rectangular parallelepiped shape and has a U-shaped transverse cross-section that is constant along a displacement direction of the first assembly relative to the second assembly.

8. The passive gravity compensator according to claim 1, wherein the magnet holder of the first assembly includes a frame having an opening inside of which is mounted the permanent magnet of the first assembly with two opposite sides facing the first and second permanent magnets of the second assembly.

9. The passive gravity compensator according to claim 1, wherein the first assembly includes two L-shaped lateral parts mounted on both sides of the frame and within a same plane of respective opposite parts of the magnetic yoke.

10. The passive gravity compensator according to claim 1, wherein a polarity of the permanent magnet of the first assembly and a polarity of the first and second permanent magnets of the second assembly are oriented in a same direction.

11. The passive gravity compensator according to claim 1, wherein the gravity compensation force is oriented in the Z-direction.

12. The passive gravity compensator according to claim 1, wherein the gravity compensation force is adjustable in a range between 5 N and 35 N.

13. The passive gravity compensator according to claim 1, wherein the gravity compensation force is constant over a predetermined stroked length between the first assembly and the second assembly.

14. The passive gravity compensator according to claim 1, wherein the magnetic yoke includes through-holes, each through-hole adapted to receive a mounting screw to affix the second assembly to one of the stationary unit and the movable unit.

15. The passive gravity compensator according to claim 8, wherein the frame is arranged as a non-magnetic frame.

16. A semiconductor equipment, comprising:
a stationary unit;
a movable unit adapted to move relative the stationary unit in a Z-direction; and
a gravity compensator as recited in claim 1;
wherein the force adjustment device is arranged as part of the first assembly of the gravity compensator; and
wherein the first assembly is mounted on the stationary unit and the second assembly is mounted on the movable unit such that the permanent magnet of the first assembly is movable inside the gap between the first and second permanent magnets of the second assembly.

17. The semiconductor equipment according to claim 16, wherein the semiconductor equipment is arranged as a wafer holder.

18. The semiconductor equipment according to claim 16, wherein the magnetic yoke includes through-holes and screws arranged in the through-holes and screwed into the movable unit.

19. The semiconductor equipment according to claim 16, further comprising a linear bearing mounted between the stationary unit and the movable unit and adapted to guide the movable unit relative to the stationary unit along the Z-direction.

20. A semiconductor equipment, comprising:
a stationary unit;
a movable unit adapted to move relative the stationary unit in a Z-direction; and
a gravity compensator as recited in claim 1;
wherein the force adjustment device is arranged as part of the first assembly of the gravity compensator; and
wherein the first assembly is mounted on a first one of the stationary unit and the movable unit and the second assembly is mounted on a second one of the stationary unit and the movable unit such that the permanent magnet of the first assembly is movable inside the gap between the first and second permanent magnets of the second assembly.
